(19) United States
(12) Patent Application Publication
(10) Pub. No.: US 2017/0346390 A1
(43) Pub. Date: Nov. 30, 2017

(54) Electrical noise elimination structure

(71) Applicant: Chung Liang LIN, Taipei City (TW)

(72) Inventor: Chung Liang LIN, Taipei City (TW)

(21) Appl. No.: 15/163,703

(22) Filed: May 25, 2016

(51) Int. Cl. H02M 1/44; H03H 7/06; H03H 7/01; H03M 1/12; H02M 7/44

(52) U.S. Cl. CPC H02M 1/44; H03M 1/124; H02M 7/44; H03H 7/0153; H03H 7/06

(57) ABSTRACT

An electrical noise elimination structure contains: a casing in which a plurality of terminals, multiple wave filtration modules, a control unit, an AC-DC power processing circuit, a microprocessor, an ADC sampling circuit, and a potential generation circuit are arranged. The plurality of terminals connect the multiple wave filtration modules to the control unit, and the control unit couples with the AC-DC power processing circuit, the AC-DC power processing circuit joins the microprocessor to the control unit, the potential generation circuit connects the ADC sampling circuit to the microprocessor, thus avoiding distortion of signal transmission and eliminating the electrical noises among the plurality of terminals, the multiple wave filtration modules, the control unit, the AC-DC power processing circuit, the microprocessor, the ADC sampling circuit, and the potential generation circuit.

### FIELD OF THE INVENTION

The present invention relates to an electrical noise elimination structure which avoids distortion of signal transmission and eliminates the electrical noises among the plurality of terminals, the multiple wave filtration modules, the control unit, the AC-DC power processing circuit, the microprocessor, the ADC sampling circuit, and the potential generation circuit.

### BACKGROUND OF THE INVENTION

Typically, between transmission end and receiving end produces impedance matching so as to transmit signals well, but error of receiving the signals will occur in long-distance transmission or high input impedance, thereby causing Jitter or bit loss. A conventional signal device contains grounding conductor so as to reduce conductor as signal transmission. However, among multiple signal devices in a system, at least one signal wire are employed to connect the multiple signal devices, thus producing electrical noises easily.

The present invention has arisen to mitigate and/or obviate the afore-described disadvantages.

### SUMMARY OF THE INVENTION

The primary objective of the present invention is to provide an electrical noise elimination structure which avoids distortion of signal transmission and eliminates the electrical noises among the plurality of terminals, the multiple wave filtration modules, the control unit, the AC-DC power processing circuit, the microprocessor, the ADC sampling circuit, and the potential generation circuit.

To obtain the above objective, an electrical noise elimination structure provided by the present invention contains: a casing in which a plurality of terminals, multiple wave filtration modules, a control unit, an AC-DC power processing circuit, a microprocessor, an ADC sampling circuit, and a potential generation circuit are arranged.

The plurality of terminals connect the multiple wave filtration modules to the control unit, and the control unit couples with the AC-DC power processing circuit, the AC-DC power processing circuit joins the microprocessor to the control unit, and the potential generation circuit connects the ADC sampling circuit to the microprocessor.

The plurality of terminals are configured to connect multiple devices toward a ground, respectively.

The multiple wave filtration modules are provided for filtering electrical noises from the plurality of terminals.

The control unit collects and switches filtered waves from the plurality of terminals.

The microprocessor is applied to control the electrical noise elimination structure.

Between the potential generation circuit and the supply mains produces opposite potential.

The ADC sampling circuit is employed to transform environment potential into digital data, and the AC-DC power processing circuit is configured to convert alternating current of the supply mains into direct current of the supply mains and to provide a signal path to the control unit.

Preferably, the plurality of terminals, the multiple wave filtration modules, the control unit, the AC-DC power processing circuit, the microprocessor, the ADC sampling circuit, and the potential generation circuit are connected together so as to decrease distortion of signal transmission.

Preferably, each of the plurality of terminals has a respective one of the multiple wave filtration modules so as to filter the electrical noises, wherein the respective one wave filtration module has a filtering network comprised of resistance, capacitance, and inductance and has an antenna for forming Eddy currents from the electrical noises, and the respective one wave filtration module converts electromagnetic waves into heat energy.

Preferably, the control unit switches signal paths by using a mechanical relay or a solid state relay and releases the signal paths.

Preferably, among the potential generation circuit and the neutral wire and the live wire of the supply mains forms the potential difference so as to judge a phase of the neutral wire and the live wire of the supply mains.

Preferably, the AC-DC power processing circuit does not have a transformer circuit and is used to connect the control unit to the supply mains.

Preferably, the AC-DC power processing circuit has a transformer circuit and is used to connect the control unit to the supply mains.

Preferably, the signal path is the neutral wire of the supply mains.

Preferably, the signal path is an earth wire of the supply mains.

Preferably, the multiple wave filtration modules have at least one parallel wave filters disposed thereamong so as to filter high-frequency noises from AC power supply.

### BRIEF DESCRIPTION OF THE DRAWINGS

FIG. 1 is a schematic view showing the operation of an electrical noise elimination structure according to a preferred embodiment of the present invention.

FIG. 2 is a schematic view showing the configuration of the electrical noise elimination structure according to the preferred embodiment of the present invention.

FIG. 3 is another schematic view showing the operation of the electrical noise elimination structure according to the preferred embodiment of the present invention.

### DETAILED DESCRIPTION OF THE FIRST EMBODIMENTS

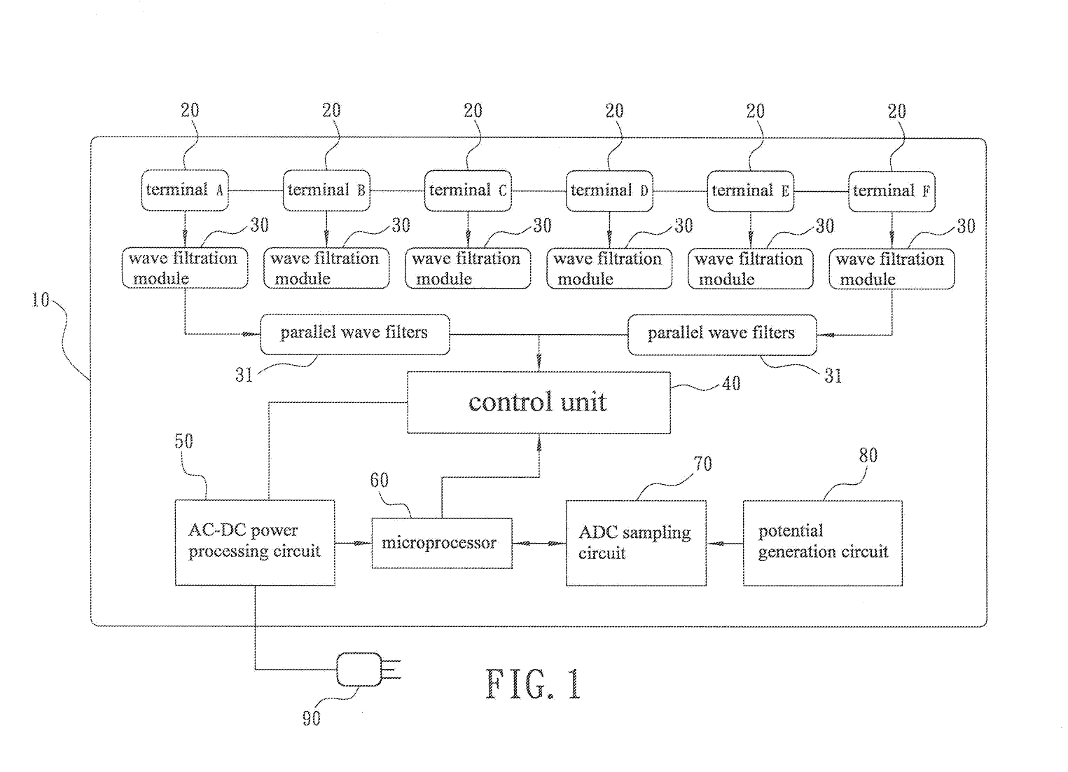

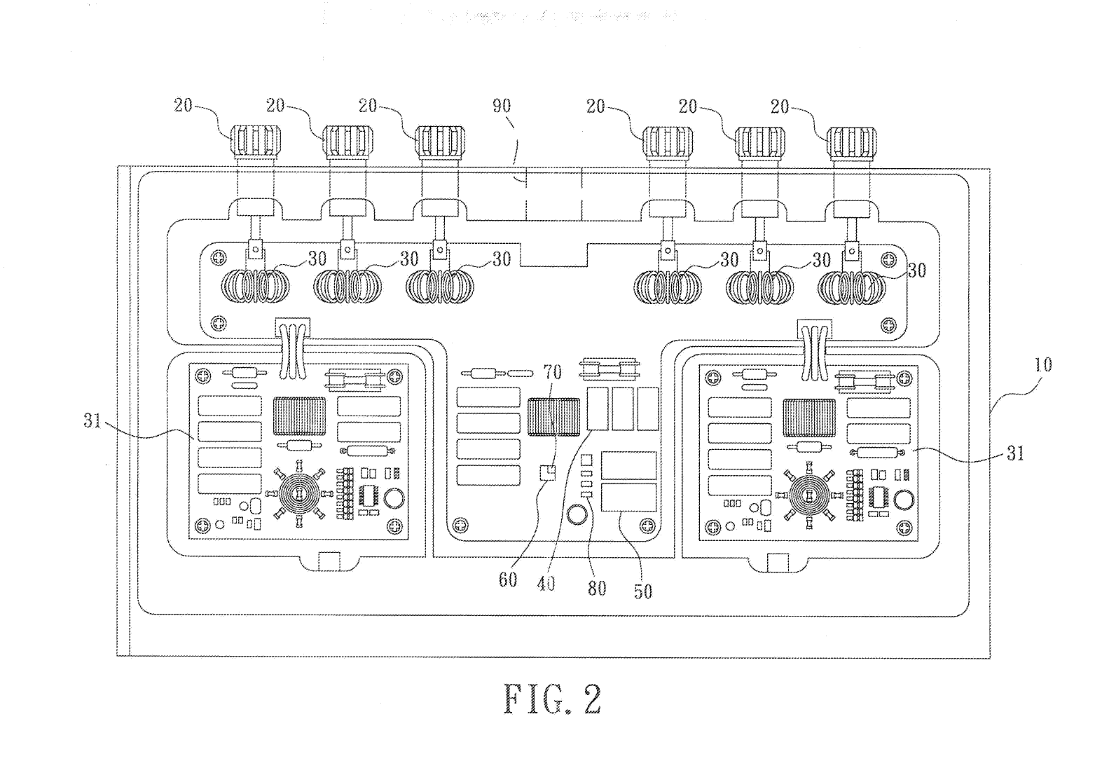

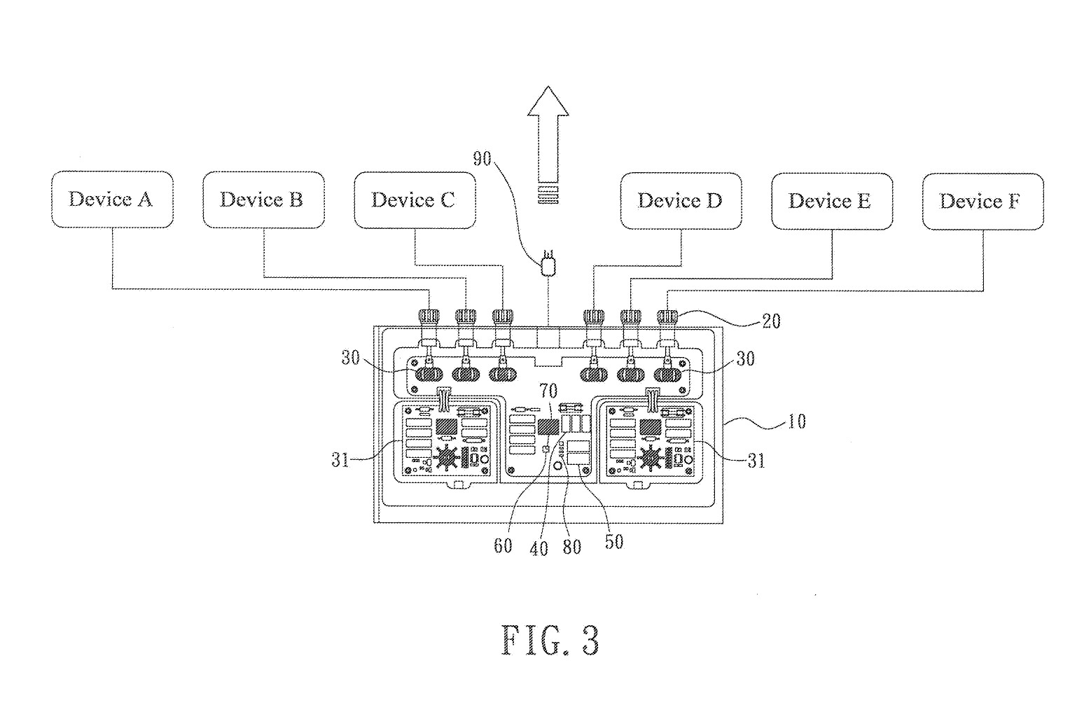

With reference to FIGS. 1 to 3, an electrical noise elimination structure according to a preferred embodiment of the present invention comprises: a casing 10 in which a plurality of terminals 20, multiple wave filtration modules 30, a control unit 40, an AC-DC power processing circuit 50, a microprocessor 60, an ADC sampling circuit 70, and a potential generation circuit 80 are arranged. The plurality of terminals 20 connect the multiple wave filtration modules 30 to the control unit 40, and the control unit 40 couples with the AC-DC power processing circuit 50, the AC-DC power processing circuit 50 joins the microprocessor 60 to the control unit 40, the potential generation circuit 80 connects the ADC sampling circuit 70 to the microprocessor 60, and the AC-DC power processing circuit 50 is in connection with supply mains 90.

The plurality of terminals 20 are configured to connect multiple devices A to F toward a ground, respectively. The multiple wave filtration modules 30 are provided for filtering electrical noises from the plurality of terminals 20 and have at least one parallel wave filters 31 disposed thereamong so as to filter high-frequency noises from AC power supply. The control unit 40 collects and switches filtered waves from the plurality of terminals 20. The microprocessor 60 is applied to control the electrical noise elimination structure. Between the potential generation circuit 80 and the supply mains 90 produces opposite potential, and each of the multiple devices A to F has a reference point. In addition, among the potential generation circuit 50 and a neutral wire and a live wire of the supply mains 90 forms a potential difference so as to judge a phase of the neutral wire and the live wire of the supply mains 90. The ADC sampling circuit 70 is employed to transform environment potential into digital data. The AC-DC power processing circuit 50 is configured to convert alternating current of the supply mains 90 into direct current of the supply mains 90 and to provide signal paths to the control unit 40, thus avoiding distortion of signal transmission and eliminating the electrical noises among the multiple devices. It is to be noted that the control unit 40 switches signal paths by using a mechanical relay or a solid state relay and releases the signal paths.

Preferably, each of the plurality of terminals 20 has a respective one of the multiple wave filtration modules 30 so as to filter the electrical noises, wherein the respective one wave filtration module 30 has a filtering network comprised of resistance, capacitance, and inductance and has an antenna for forming Eddy currents from the electrical noises. Thereafter, the respective one wave filtration module 30 converts electromagnetic waves into heat energy and guides a respective one of multiple earth wires of the multiple wave filtration modules 30 into the control unit 40 so as to obtain zero grounding potential among the multiple devices.

The potential generation circuit 80 produces the potential difference between the neutral wire and the live wire of the supply mains 90 based on conditions. The ADC sampling circuit 70 transforms the potential difference environment potential into the digital data which will be sent to the microprocessor 60 for calculation.

After the microprocessor 60 judges the phase of the neutral wire and the live wire of the supply mains 90, the control unit 40 switches the phase, and zero points of the plurality of terminals, the multiple wave filtration modules, the control unit, the AC-DC power processing circuit, the microprocessor, the ADC sampling circuit, and the potential generation circuit are coupled with ground potential of the supply mains 90, thus obtaining reference zero and zero ground potential to prevent signal interference and distortion.

Furthermore, the AC-DC power processing circuit 50 does not have a transformer circuit and is used to connect the control unit 40 to the supply mains 90. Alternatively, the AC-DC power processing circuit 50 has a transformer circuit and is used to connect the control unit 40 to the supply mains 90. The signal path is the neutral wire of the supply mains 90 or is an earth wire of the supply mains 90.

Between the potential generation circuit 80 and the supply mains 90 produces the opposite potential, and between the neutral wire and the live wire of the supply mains 90 forms the potential difference so as to judge the phase of the neutral wire and the live wire of the supply mains 90.

While the first embodiments of the invention have been set forth for the purpose of disclosure, modifications of the disclosed embodiments of the invention as well as other embodiments thereof may occur to those skilled in the art. The scope of the claims should not be limited by the first embodiments set forth in the examples, but should be given the broadest interpretation consistent with the description as a whole.

What is claimed is:

1. An electrical noise elimination structure comprising: a casing in which a plurality of terminals, multiple wave filtration modules, a control unit, an AC-DC power processing circuit, a microprocessor, an ADC sampling circuit, and a potential generation circuit are arranged; wherein
the plurality of terminals connect the multiple wave filtration modules to the control unit, and the control unit couples with the AC-DC power processing circuit, the AC-DC power processing circuit joins the microprocessor to the control unit, and the potential generation circuit connects the ADC sampling circuit to the microprocessor;
the plurality of terminals are configured to connect multiple devices toward a ground, respectively;
the multiple wave filtration modules are provided for filtering electrical noises from the plurality of terminals;
the control unit collects and switches filtered waves from the plurality of terminals;
the microprocessor is applied to control the electrical noise elimination structure;
between the potential generation circuit and the supply mains produces opposite potential;
the ADC sampling circuit is employed to transform environment potential into digital data; and
the AC-DC power processing circuit is configured to convert alternating current of the supply mains into direct current of the supply mains and to provide a signal path to the control unit.

2. The electrical noise elimination structure as claimed in claim 1, wherein the plurality of terminals, the multiple wave filtration modules, the control unit, the AC-DC power processing circuit, the microprocessor, the ADC sampling circuit, and the potential generation circuit are connected together so as to decrease distortion of signal transmission.

3. The electrical noise elimination structure as claimed in claim 1, wherein each of the plurality of terminals has a respective one of the multiple wave filtration modules so as to filter the electrical noises, wherein the respective one wave filtration module has a filtering network comprised of resistance, capacitance, and inductance and has an antenna for forming Eddy currents from the electrical noises, and the respective one wave filtration module converts electromagnetic waves into heat energy.

4. The electrical noise elimination structure as claimed in claim 1, wherein the control unit switches signal paths by using a mechanical relay or a solid state relay and releases the signal paths.

5. The electrical noise elimination structure as claimed in claim 1, wherein among the potential generation circuit and the neutral wire and the live wire of the supply mains forms the potential difference so as to judge a phase of the neutral wire and the live wire of the supply mains.

6. The electrical noise elimination structure as claimed in claim 1, wherein the AC-DC power processing circuit does not have a transformer circuit and is used to connect the control unit to the supply mains.

7. The electrical noise elimination structure as claimed in claim 1, wherein the AC-DC power processing circuit has a transformer circuit and is used to connect the control unit to the supply mains.

8. The electrical noise elimination structure as claimed in claim 4, wherein the signal path is the neutral wire of the supply mains.

9. The electrical noise elimination structure as claimed in claim 4, wherein the signal path is an earth wire of the supply mains.

10. The electrical noise elimination structure as claimed in claim 4, wherein the multiple wave filtration modules have at least one parallel wave filters disposed thereamong so as to filter high-frequency noises from AC power supply.
